(19) United States
(12) Patent Application Publication
(10) Pub. No.: US 2023/0010438 A1
(43) Pub. Date: Jan. 12, 2023

(54) SEMICONDUCTOR DEVICES AND METHODS OF MANUFACTURING THEREOF

(71) Applicant: Taiwan Semiconductor Manufacturing Company, Ltd., Hsinchu (TW)

(72) Inventors: Wen-Hao Cheng, Taichung City (TW); Hsuan-Chih Chu, Changhua County (TW); Yen-Yu Chen, Taichung City (TW)

(73) Assignee: Taiwan Semiconductor Manufacturing Company, Ltd., Hsinchu (TW)

(21) Appl. No.: 17/585,252

(22) Filed: Jan. 26, 2022

Related U.S. Application Data
(60) Provisional application No. 63/219,673, filed on Jul. 8, 2021.

(51) Int. Cl. H01L 23/532; H01L 21/02; H01L 23/535; H01L 21/762

(52) U.S. Cl. CPC H01L 23/5329; H01L 21/02425; H01L 23/535; H01L 21/02488; H01L 21/762

(57) ABSTRACT

A semiconductor device includes a device feature. The semiconductor device includes a first silicide layer having a first metal, wherein the first silicide layer is embedded in the device feature. The semiconductor device includes a second silicide layer having a second metal, wherein the second silicide layer, disposed above the device feature, comprises a first portion directly contacting the first silicide layer. The first metal is different from the second metal.

### CROSS-REFERENCE TO RELATED APPLICATION

This application claims priority to and the benefit of U.S. Provisional Application No. 63/219,673, filed Jul. 8, 2021, entitled “SEMICONDUCTOR STRUCTURE AND MANUFACTURING METHOD THEREOF,” which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is an example flow chart of a method for fabricating a semiconductor device, in accordance with some embodiments.

FIGS. 2, 3, 4, 5, 6, 7, 8, 9, and 10 illustrate cross-sectional views of an example semiconductor device during various fabrication stages, made by the method of FIG. 1, in accordance with some embodiments.

FIG. 11 is an example flow chart of a method for fabricating a semiconductor device, in accordance with some embodiments.

FIGS. 12, 13, 14, 15, 16, 17, 18, 19, and 20 illustrate cross-sectional views of an example semiconductor device during various fabrication stages, made by the method of FIG. 11, in accordance with some embodiments.

FIG. 21 illustrate a cross-sectional view of an example image sensor including a number of stacks of different silicide layers, made by the method of FIG. 1 or 11, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, an image sensor includes active image sensing elements in a pixel region, such as photodiodes and transistor structures (e.g., transfer gate transistors, reset transistors). These transistor structures, as well as devices used for control and signal circuits in a peripheral circuit region, or used for peripheral logic circuits, are typically fabricated based on complementary metal oxide semiconductor (CMOS) technologies. Therefore to reduce process cost and complexity, the active image sensing elements may also have been fabricated using the same CMOS technologies. This approach, however, can influence the quality of the image sensors. For example, a metal silicide layer is typically formed on a source/drain region and/or gate structure of each of those CMOS transistors (which is sometimes referred to as Self-ALigned metal silICIDE, (Salicide)). With such a metal silicide layer formed on the active image sensing elements, unwanted leakages (e.g., in the form of dark current generation) can be induced, which can disadvantageously degrade signal-to-noise ratios of the image sensor as a whole. In this regard, one type of metal silicide layer, essentially containing titanium silicide (TiSi₂), has been proposed to solve the leakage issues. Even with the leakage current substantially decreased, such a TiSi₂ layer typically results in a high contact resistance (e.g., in the range of about 60 μΩ·cm to about 80 μΩ·cm). As dimensions of the transistors continue to shrink, this high contact resistance issue can only become severer.

The present disclosure provides various embodiments of a semiconductor device including a stack of multiple different silicide layers formed at the contact of one or more device features. In various embodiments, the stack includes at least a lower silicide layer containing a first metal, and an upper silicide layer containing a second, different metal. The lower silicide layer, which is electrically coupled to a silicon-based device feature (e.g., a source/drain region, a gate structure), may include titanium silicide (TiSi₂), and the upper silicide layer, which is electrically coupled to a metal-based contact structure (e.g., a plug), may include nickel silicide (NiSi). In such a configuration, a total contact resistance can be significantly reduced (e.g., by about 20% to 80%), without suffering from the leakage issues. Further, this stack-based configuration of different silicide layers can be flexibly fabricated in various manners. For example, the lower silicide layer can be formed along a top surface of the silicon-based device feature, and while contacting the lower silicide layer, the upper silicide layer can be formed as liner layer contacting the metal-based contact structure. In another example, the lower silicide layer can be formed along a top surface of the silicon-based device feature, and while contacting the lower silicide layer, the upper silicide layer can be formed as planar layer contacting the metal-based contact structure.

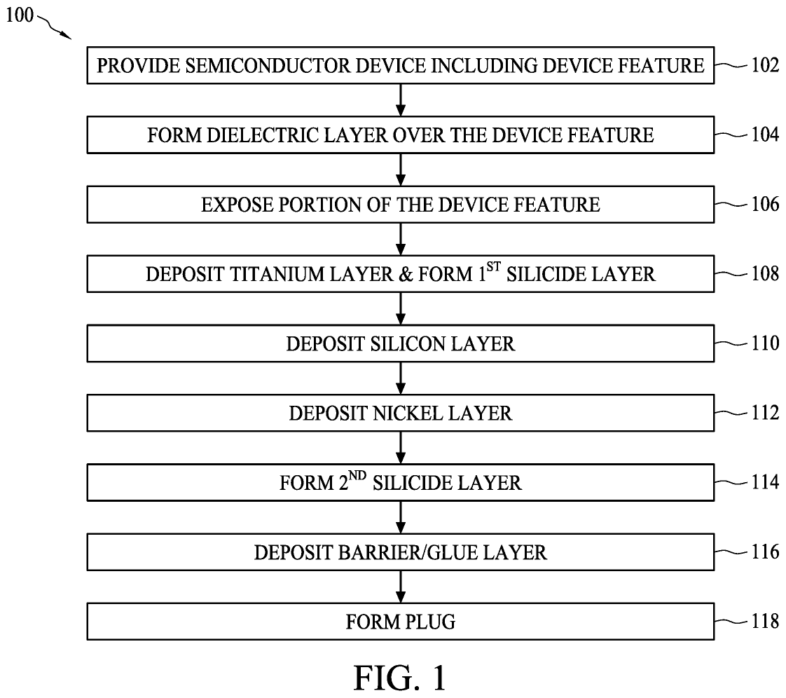

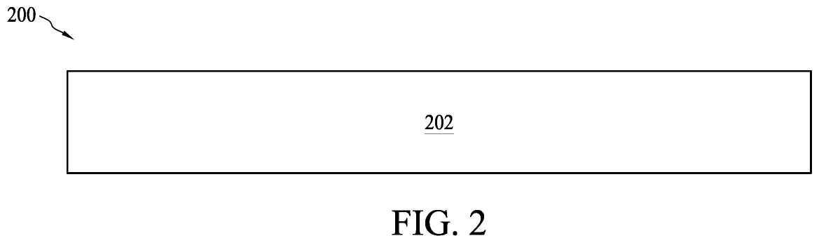

FIG. 1 is a flowchart illustrating a method 100 for fabricating a semiconductor device (e.g., an image sensor) 200, according to various aspects of the present disclosure. FIGS. 2, 3, 4, 5, 6, 7, 8, 9, and 10 show schematic cross-sectional views of the semiconductor device 200 at various stages of fabrication according to an embodiment of the method 100 of FIG. 1. The semiconductor device 200 may be included in a microprocessor, memory device, and/or other integrated circuit (IC). It is noted that the method of FIG. 1 does not produce a completed semiconductor device 200. A completed semiconductor device 200 may be fabricated using complementary metal-oxide-semiconductor (CMOS) technology processing. Accordingly, it is understood that additional steps may be provided before, during, and after the method 100 of FIG. 1, and that some other steps may only be briefly described herein. Also, FIGS. 2 through 10 are simplified for a better understanding of the present disclosure. For example, although the figures illustrate the semiconductor device 200, it is understood the IC may include a number of other components such as, for example, transistors, resistors, capacitors, inductors, fuses, etc.

Referring to FIGS. 1 and 2, the method 100 begins at step 102 in which a device feature 202 is provided, in accordance with various embodiments. In general, the device feature 202 includes an active feature of the semiconductor device 200 that is configured to provide a certain device function. Such a device feature is configured to conduct electricity based on a (e.g., voltage) signal applied on a coupled metal plug (structure), which will be discussed below.

According to various embodiments, the device feature 202 includes a semiconductor material such as, for example, silicon (Si), or is otherwise Si-based. In one aspect, the device feature may be an epitaxially grown Si structure or an implanted Si well, which can function as the source/drain region (structure or terminal) of a transistor or the cathode/anode (terminal or structure) of a diode. The epitaxially grown Si structure may be formed as a three-dimensional structure having some portions protruding from the major surface of a semiconductor substrate. The implanted Si may be formed as a structure recessed from the major surface of a semiconductor substrate. In another aspect, the device feature may be a poly-Si structure, which can function as the gate (structure or terminal) of a transistor. Such a poly-Si structure (202) may be doped or undoped.

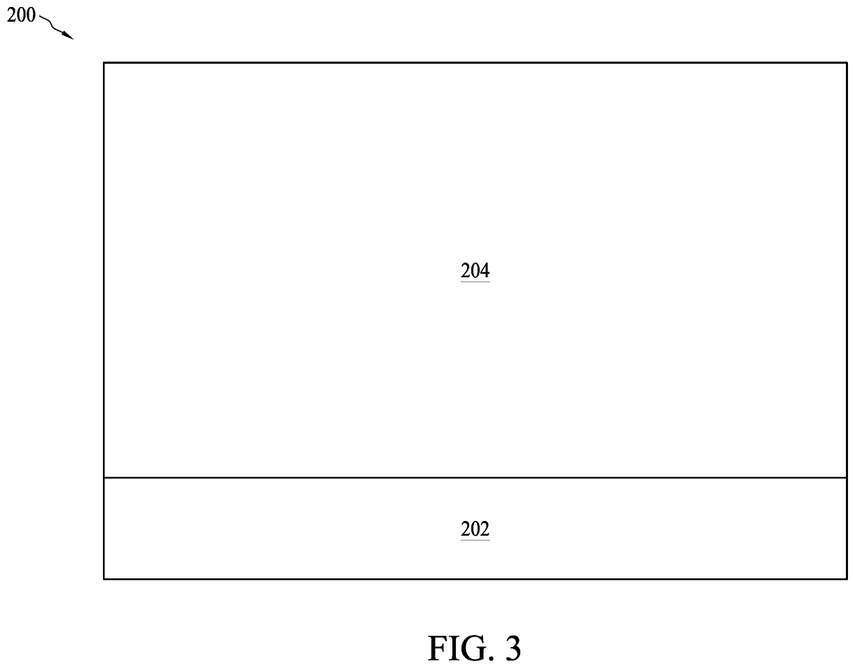

Referring to FIGS. 1 and 3, the method 100 continues to step 104 in which a dielectric layer 204 is formed over the device feature 202, in accordance with various embodiments. The dielectric layer 204 can form a portion of an inter-metal dielectric (IMD) or inter-layer dielectric (ILD) layer. Such an IMD/ILD layer is sometimes referred to as a metallization layer, as the IMD/LID layer can include a number of metal structures (e.g., plugs, vias, interconnect structures, etc.) embedded therein. As will be discussed below, at least one of the metal structures can electrically couple the device feature 202 to one or more other device features.

The dielectric layer 204 may be a single layer or a multi-layered structure. In some embodiments, the dielectric layer 204 with a thickness varies with the applied technology, for example a thickness of about 1000 angstroms to about 30000 angstroms. In some embodiments, the dielectric layer 204 is silicon oxide, carbon-doped silicon oxide, a comparatively low dielectric constant (k value) dielectric material with a k value less than about 4.0, or combinations thereof. In some embodiments, the dielectric layer 204 is formed of a material, including low-k dielectric material, extreme low-k dielectric material, porous low-k dielectric material, and combinations thereof. The term “low-k” is intended to define a dielectric constant of a dielectric material of 3.0 or less. The term “extreme low-k (ELK)” means a dielectric constant of 2.5 or less, and preferably between 1.9 and 2.5. The term “porous low-k” refers to a dielectric constant of a dielectric material of 2.0 or less, and preferably 1.5 or less. A wide variety of low-k materials may be employed in accordance with embodiments, for example, spin-on inorganic dielectrics, spin-on organic dielectrics, porous dielectric materials, organic polymer, organic silica glass, FSG (SiOF series material), HSQ (hydrogen silsesquioxane) series material, MSQ (methyl silsesquioxane) series material, or porous organic series material.

In some embodiments, the dielectric layer 204 is deposited through any of a variety of techniques, such as chemical vapor deposition (CVD), physical vapor deposition (PVD), atomic layer deposition (ALD), remote plasma enhanced chemical vapor deposition (RPECVD), liquid source misted chemical deposition (LSMCD), coating, spin-coating or another process that is adapted to form a thin film layer over a semiconductor substrate.

In embodiments, the dielectric layer 204 is a nitrogen-containing layer, a carbon-containing layer, or a carbon-containing and nitrogen-containing layer for increasing corrosion resistance during a subsequent chemical mechanical polishing (CMP) process and/or increasing electromigration resistance. In one embodiment, the dielectric layer 204 is a silicon-containing and nitrogen-containing dielectric layer. In another embodiment, the dielectric layer 204 is a silicon-containing and carbon-containing dielectric layer. In yet another embodiment, the dielectric layer 204 is a silicon-containing, nitrogen-containing, and carbon-containing dielectric layer. In one embodiment, the dielectric layer 204 has a ratio by weight of carbon to silicon about equal or greater than 0.5. In another embodiment, the dielectric layer 204 has a ratio by weight of nitrogen to silicon about equal or greater than 0.3. In yet another embodiment, the dielectric layer 204 has a ratio by weight of carbon to silicon about equal or greater than 0.5 and a ratio by weight of nitrogen to silicon about equal or greater than 0.3.

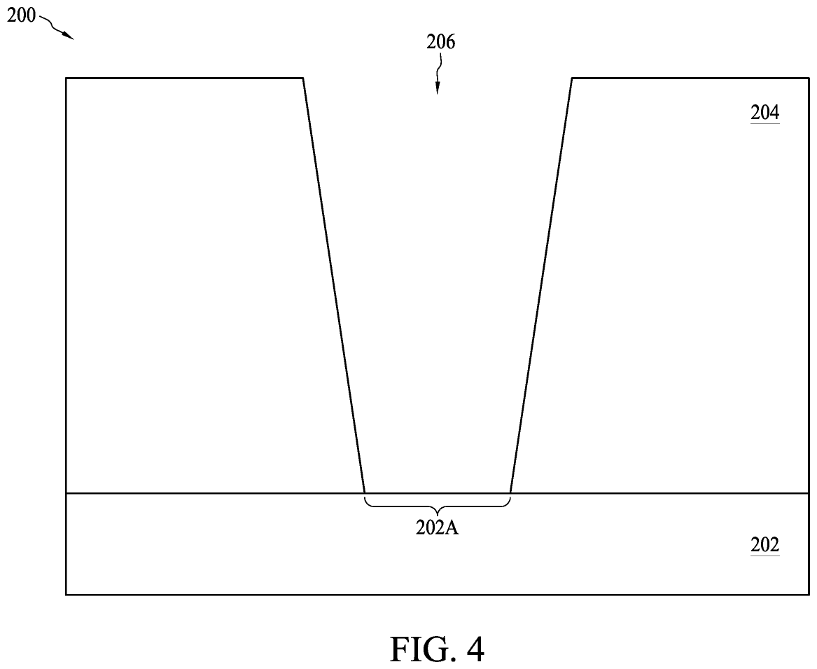

Referring to FIGS. 1 and 4, the method 100 continues to step 106 in which at least a portion (202A) of the device feature 202 is exposed, in accordance with various embodiments. In various embodiments, the portion 202A is exposed, thereby allowing the disclosed stack of silicide layers to be formed at a position around the exposed portion 202A. As shown, the portion 202A is exposed by forming a recess (or cavity) 206 extending through the dielectric layer 204. The recess 206 may be formed by performing at least some of the following processes: forming a patternable layer (e.g., a hardmask layer and/or a photoresist layer) over the dielectric layer 204; forming a hole extending through the patternable layer that defines a position of the recess 206; etching the dielectric layer 204, with the patternable layer serving as a mask, until the device feature 202 is exposed; and removing the patternable layer.

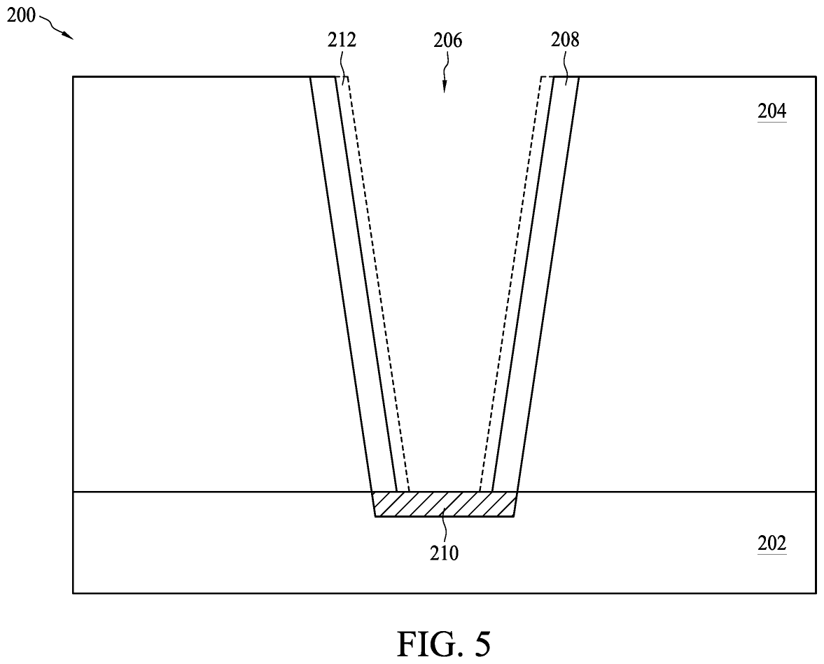

Referring to FIGS. 1 and 5, the method 100 continues to step 108 in which a titanium layer 208 is formed and a first silicide layer 210 is formed in the recess 206, in accordance with various embodiments. In various embodiments, the titanium layer 208 and first silicide layer 210 may be (e.g., concurrently) formed in a same reaction chamber (sometimes referred to as in-situ formation).

Specifically, upon forming the recess 206, the workpiece (i.e., the partially made semiconductor device 200) may be transferred to a first chamber to remove any native oxide formed over surfaces of the dielectric layer 204 and the device feature 202 through plasma of argon. Such a first chamber may sometimes be referred to as a pre-clean chamber. Next, the workpiece may be transferred to a second chamber (e.g., a chemical vapor deposition (CVD) chamber). In the second chamber, the titanium layer 208 may be first deposited as a (e.g., conformal) layer lining the recess 206, e.g., extending along sidewalls of the recess 206 and overlaying the exposed portion 202A. The titanium layer 208 may be deposited using a plasma-enhanced CVD tool, for example, through the following reaction: TiCl_{y}+H₂+Ar→TiClₓ+HCl+Ar. Such a second chamber may sometimes be referred to as a Ti chamber. Concurrently with forming the titanium layer 208, a portion of the titanium layer 208 that is at the bottom of the recess 206 may react with the exposed portion 202A having Si through a thermal process, thereby forming the first silicide layer 210. The first silicide layer 210 may be formed through the following reaction: TiClₓ+H₂+Si→TiSi₂+HCl. Accordingly, the first silicide layer 210 can essentially consist of TiSi₂.

As shown, upon forming the first silicide layer 210, the titanium layer 208 extends along the sidewalls of the recess 206, while the first silicide layer 210 is disposed at the position of the exposed portion 202A of the device feature 202. In the illustrated embodiment of FIG. 5, the first silicide layer 210 may be formed as having an upper surface that is substantially coplanar with at least a portion of an upper surface of the device feature 202, e.g., the upper surface of the first silicide layer 210 and at least the portion of the upper surface of the device feature 202 sharing a common surface. Such a common surface may be substantially flat or curved. Alternatively stated, the first silicide layer 210 may be recessed into the device feature 202 with a depth of about 10 angstroms to about 500 angstroms. In some embodiments, the depth may be in the range of about 100 angstroms to about 200 angstroms. However, it should be understood that, in addition to the portion recessed into the device feature 202, the first silicide layer 210 may include some portions that also extend along the sidewalls of the recess 206, in some other embodiments.

After forming the first silicide layer 210, the workpiece may remain in the second chamber to form an optional titanium nitride layer 212 extending the sidewalls of the recess 206, as shown in FIG. 5. The titanium nitride layer 212 may be formed by flowing nitrogen-based gas to the second chamber. For example, the titanium nitride layer 212 may be formed through the following reaction: Ti+NH₃TiN+H₂. In some embodiments, a thickness of the titanium layer 208 and the titanium nitride layer 212 (if formed) may be in the range of about 10 angstroms to about 200 angstroms.

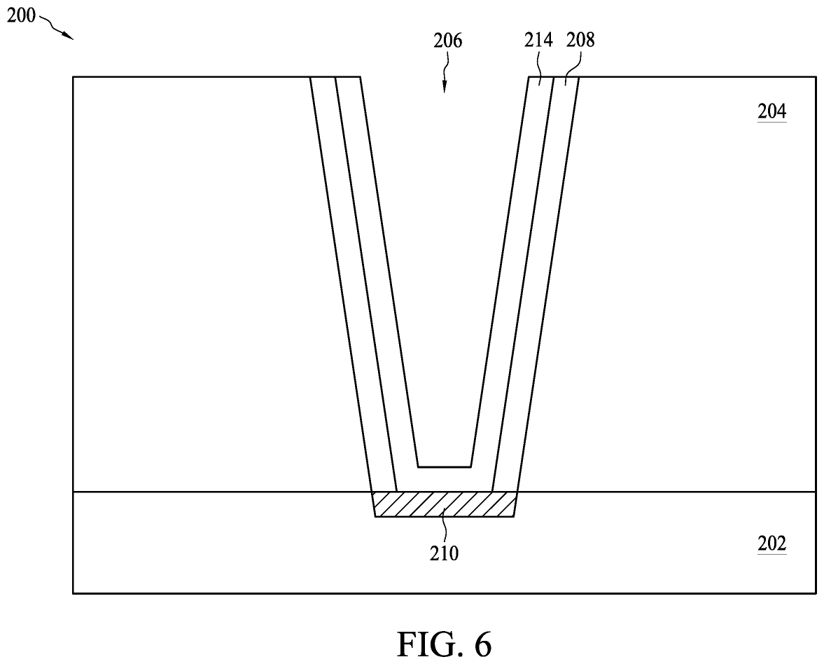

Referring to FIGS. 1 and 6, the method 100 continues to step 110 in which a silicon layer 214 is formed in the recess 206, in accordance with various embodiments. As shown, the silicon layer 214 may be formed as a (e.g., conformal) layer lining the recess 206.

In various embodiments, the silicon layer 214, in the form of poly-Si or amorphous Si, is formed through a CVD process or a diffusion process. The formation of the silicon layer 214 may be performed in a third chamber different from the pre-clean (first) chamber and from the titanium (second) chamber. For example, the silicon layer 214 can be formed using a CVD process at an elevated temperature of about 200° C. to about 300° C. based on the following reaction: SiHₓ→Si+xH. In another example, the silicon layer 214 can be formed using a diffusion process at an elevated temperature of about 500° C. to about 650° C. based on the following reaction: SiH₄→Si+2H₂.

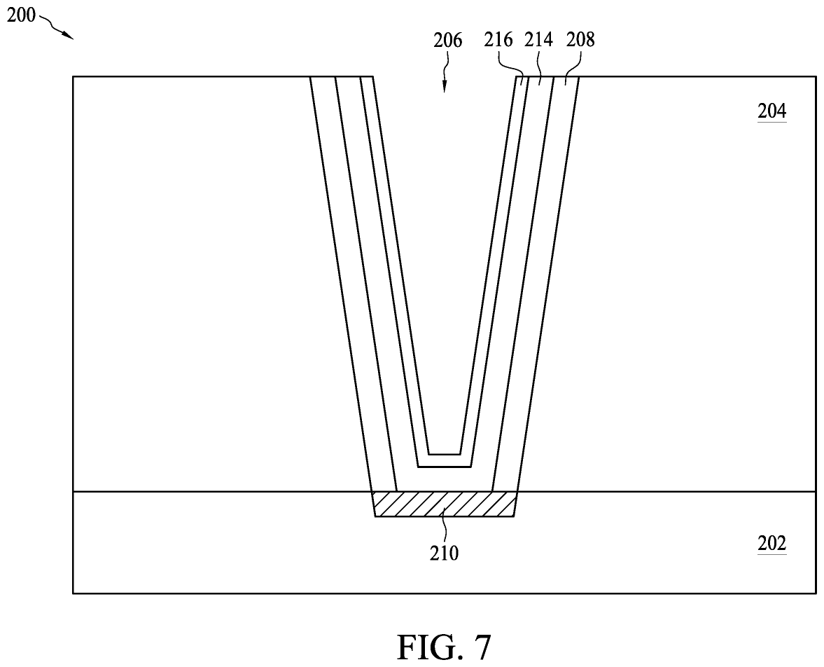

Referring to FIGS. 1 and 7, the method 100 continues to step 112 in which a nickel layer 216 is formed in the recess 206, in accordance with various embodiments. As shown, the nickel layer 216 may be formed as a (e.g., conformal) layer lining the recess 206.

In various embodiments, the nickel layer 216 may be formed in a fourth chamber different from the pre-clean (first) chamber, from the titanium (second) chamber, and from the silicon (third) chamber. Specifically, upon forming the silicon layer 214, the workpiece may be transferred to the first chamber to remove any native oxide through one or more chemical etching processes. Next, the workpiece may be transferred to a fourth chamber (e.g., a chemical vapor deposition (CVD) chamber or physical vapor deposition (PVD) chamber) to deposit the nickel layer 216. Such a fourth chamber may sometimes be referred to as a Ni chamber.

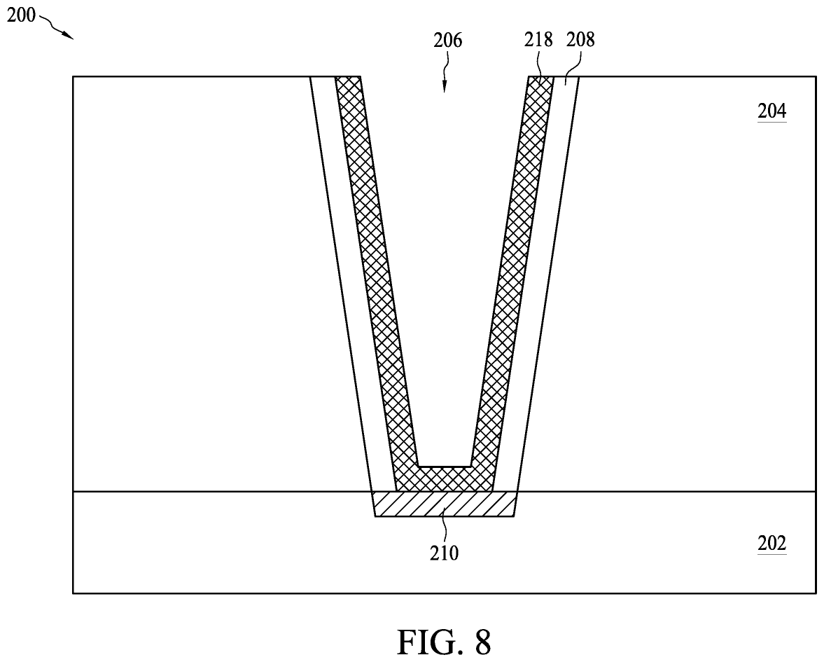

Referring to FIGS. 1 and 8, the method 100 continues to step 114 in which a second silicide layer 218 is formed in the recess 206, in accordance with various embodiments. As shown, the second silicide layer 218 may be formed as a (e.g., conformal) layer lining the recess 206.

In various embodiments, the second silicide layer 218 may be formed in the same Ni (fourth) chamber through one or more annealing processes. Specifically, the second silicide layer 218 may be formed by annealing the workpiece at one or more elevated temperatures. As such, the nickel layer 216 can react with the silicon layer 214, thereby forming the second silicide layer 218. For example, after depositing the nickel layer 216 in the Ni chamber, the workpiece is first annealed at a relatively low temperature (e.g., about 250° C.) for a relatively long period of time (e.g., about 60 seconds) to cause the nickel layer 216 to react with the silicon layer 214, thereby forming NiSi₂. Unreacted nickel may be removed from the Ni chamber. Next, still in the Ni chamber, the workpiece is annealed at a relatively high temperature (e.g., about 450° C.) for a relatively short period of time (about 25 seconds) to convert the NiSi₂ into NiSi. Accordingly, the second silicide layer 218 essentially consists of NiSi. In some embodiments, a thickness of the second silicide layer 218 may be in the range of about 10 angstroms to about 500 angstroms.

Upon forming the second silicide layer 218, the disclosed stack of silicide layers 210 and 218, each of which contains different metals, can be formed. With such a stacked configuration, various advantages can be provided over the existing silicide layers. For example, with the first silicide layer 210 that contains titanium formed in (or otherwise in contact with) the Si-based device feature 202, leakage current can be substantially suppressed. Further, with the second silicide layer 218 that contains nickel disposed over (or otherwise in contact with) the first silicide layer 210, a total of contact resistance of such a stack of silicide layers 210 and 218 can be averaged down, as NiSi generally has a much lower resistivity than TiSi₂ (e.g., about 14˜20 μΩ·cm as opposed to about 60˜80 μΩ·cm). As such, a contact structure (e.g., a plug which will be discussed below), formed to electrically couple the device feature 202 to one or more other device features, can conduct current with substantially low leakage while experiencing a significantly limited amount of contact resistance.

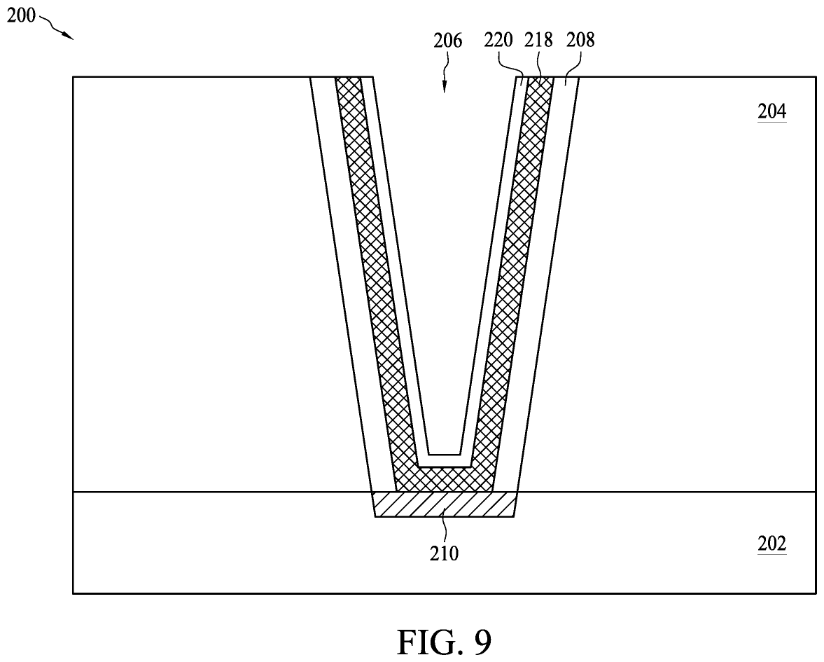

Referring to FIGS. 1 and 9, the method 100 continues to step 116 in which a barrier/glue layer 220 is formed in the recess 206, in accordance with various embodiments. As shown, the barrier/glue layer 220 may be formed as a (e.g., conformal) layer lining the recess 206.

In some embodiments, the barrier/glue layer 220 can serve as a barrier to protect the overlaid components (e.g., the device feature 202, the silicide layers 210 and 218, etc.) from being damaged during one or more later processes. Alternatively or additionally, the barrier/glue layer 220 can serve as a glue layer to assure a later formed meal structure to be in close contact with the silicide layer 218. The barrier/glue layer 220 may be formed of titanium nitride, but it should be understood that the barrier/glue layer 220 can be formed of any of various other materials (e.g., tantalum nitride, tantalum nitride silicon, titanium tungsten, titanium nitride silicon, or combinations thereof), while remaining within the scope of the present disclosure. The barrier/glue layer 220 can be formed through a CVD process. The formation of the barrier/glue layer 220 may be performed in a fifth chamber different from the above-described chambers. For example, after forming the second silicide layer 218, the workpiece may be transferred from the fourth (Ni) chamber to a fifth chamber in which the barrier/glue layer 220 is formed using a CVD process at an elevated temperature of about 540° C. based on the following reaction: TiCl_{y}+NH₃→TiN+HCl+N₂. Such a fifth chamber may sometimes be referred to as a TiN chamber.

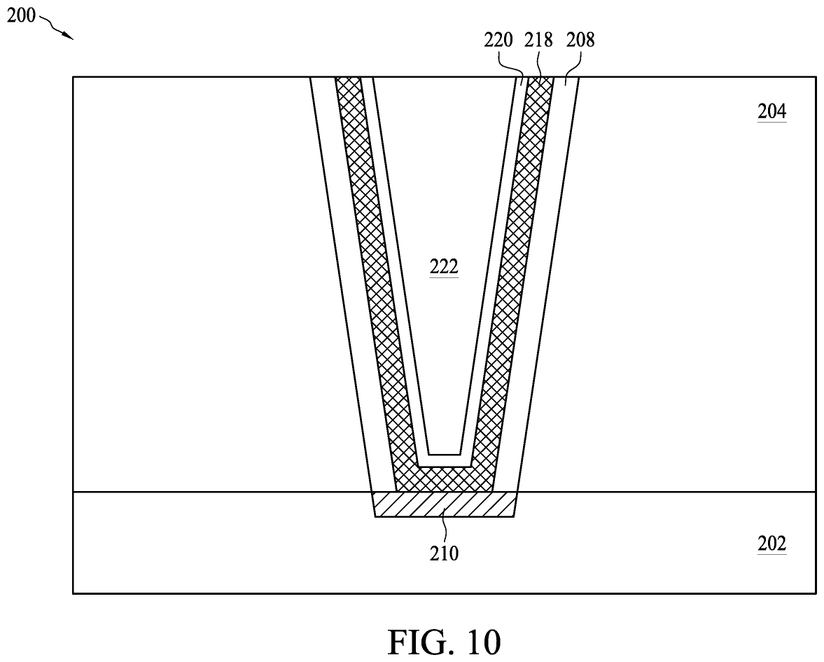

Referring to FIGS. 1 and 10, the method 100 continues to step 118 in which a plug 222 is formed in the recess 206 (FIG. 9), in accordance with various embodiments. As shown, the plug 222 may be formed to fill (a remaining portion of) the recess 206.

The plug 222 is formed to allow the device feature 202 to be electrically coupled to one or more other device features (e.g., one or more other source/drain terminals, one or more other gate terminals, one or more signal lines, one or more power rails, etc.). For example, the device feature 202 can conduct electricity for the transistor to which the device feature 202 belongs by applying a (e.g., voltage) signal on the plug 222. Such a signal can be applied to the deice feature 202 through the barrier/glue layer 220, and the stack of silicide layers 218 and 210. With the second silicide layer 218 interposed between the plug 222 and the device feature 202, the contact resistance between the plug and device feature 202 can be significantly reduced.

In various embodiments, the plug 222 is formed of a metal material such as, for example, tungsten. However, it should be understood that the plug 222 can be formed of any of various other metal materials (e.g., copper, tantalum, indium, tin, zinc, manganese, chromium, titanium, platinum, aluminum, or combinations thereof), while remaining within the scope of the present disclosure. In some embodiments, the plug 222 is formed using an electro-chemical plating (ECP) process, physical vapor deposition (PVD), chemical vapor deposition (CVD), plasma enhanced CVD (PECVD), low pressure CVD (LPCVD), atomic layer deposition (ALD), or other deposition techniques to deposit the above-mentioned metal material(s) into the recess 206, followed by a chemical mechanical polishing (CMP) process.

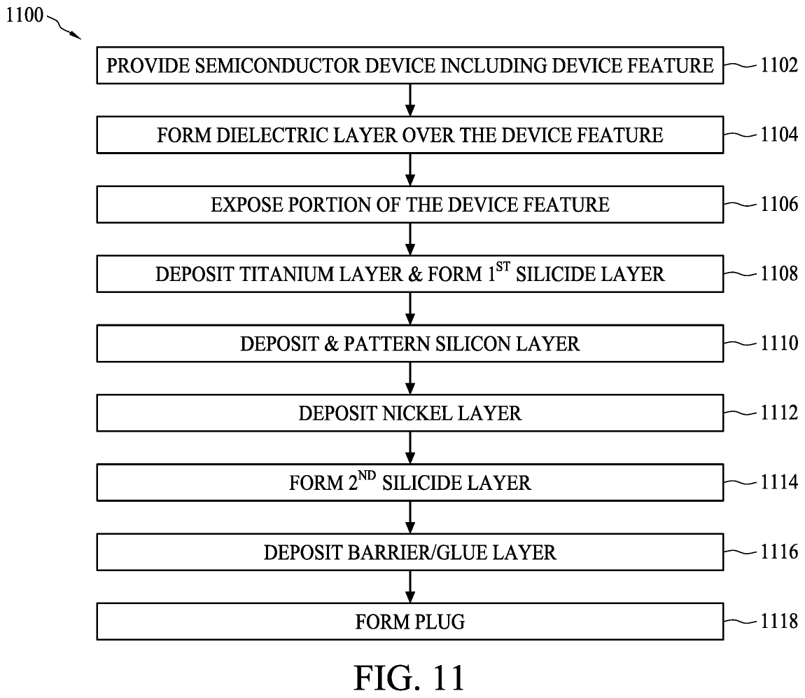

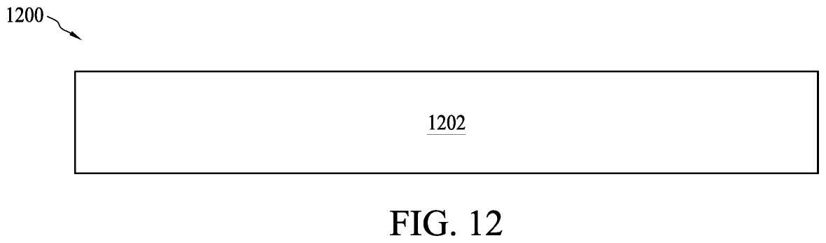

FIG. 11 is a flowchart illustrating another method 1100 for fabricating a semiconductor device (e.g., an image sensor) 1200, according to various aspects of the present disclosure. FIGS. 12, 13, 14, 15, 16, 17, 18, 19, and 20 show schematic cross-sectional views of the semiconductor device 1200 at various stages of fabrication according to an embodiment of the method 1100 of FIG. 11. The semiconductor device 1200 may be included in a microprocessor, memory cell, and/or other integrated circuit (IC). It is noted that the method of FIG. 11 does not produce a completed semiconductor device 1200. A completed semiconductor device 1200 may be fabricated using complementary metal-oxide-semiconductor (CMOS) technology processing. Accordingly, it is understood that additional steps may be provided before, during, and after the method 1100 of FIG. 11, and that some other steps may only be briefly described herein. Also, FIGS. 12 through 20 are simplified for a better understanding of the present disclosure. For example, although the figures illustrate the semiconductor device 1200, it is understood the IC may include a number of other components such as, for example, transistors, resistors, capacitors, inductors, fuses, etc.

Referring to FIGS. 11 and 12, the method 1100 begins at step 1102 in which a device feature 1202 is provided, in accordance with various embodiments. In general, the device feature 1202 includes an active feature of the semiconductor device 1200 that is configured to provide a certain device function. Such a device feature is configured to conduct electricity based on a (e.g., voltage) signal applied on a coupled metal plug (structure), which will be discussed below.

According to various embodiments, the device feature 1202 includes a semiconductor material such as, for example, silicon (Si), or is otherwise Si-based. In one aspect, the device feature may be an epitaxially grown Si structure or an implanted Si well, which can function as the source/drain region (structure or terminal) of a transistor or the cathode/anode (terminal or structure) of a diode. The epitaxially grown Si structure may be formed as a three-dimensional structure having some portions protruding from the major surface of a semiconductor substrate. The implanted Si will may be formed as a structure recessed from the major surface of a semiconductor substrate. In another aspect, the device feature may be a poly-Si structure, which can function as the gate (structure or terminal) of a transistor. Such a poly-Si structure (1202) may be doped or undoped.

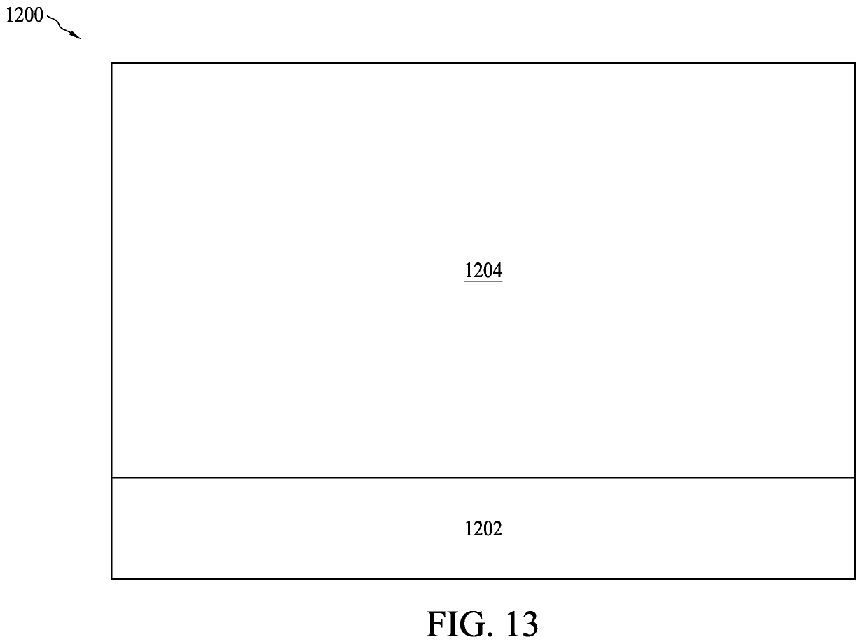

Referring to FIGS. 11 and 13, the method 1100 continues to step 1104 in which a dielectric layer 1204 is formed over the device feature 1202, in accordance with various embodiments. The dielectric layer 1204 can form a portion of an inter-metal dielectric (IMD) or inter-layer dielectric (ILD) layer. Such an IMD/ILD layer is sometimes referred to as a metallization layer, as the IMD/LID layer can include a number of metal structures (e.g., plugs, vias, interconnect structures, etc.) embedded therein. As will be discussed below, at least one of the metal structures can electrically couple the device feature 1202 to one or more other device features.

The dielectric layer 1204 may be a single layer or a multi-layered structure. In some embodiments, the dielectric layer 1204 with a thickness varies with the applied technology, for example a thickness of about 1000 angstroms to about 30000 angstroms. In some embodiments, the dielectric layer 1204 is silicon oxide, carbon-doped silicon oxide, a comparatively low dielectric constant (k value) dielectric material with a k value less than about 4.0, or combinations thereof In some embodiments, the dielectric layer 1204 is formed of a material, including low-k dielectric material, extreme low-k dielectric material, porous low-k dielectric material, and combinations thereof. The term “low-k” is intended to define a dielectric constant of a dielectric material of 3.0 or less. The term “extreme low-k (ELK)” means a dielectric constant of 2.5 or less, and preferably between 1.9 and 2.5. The term “porous low-k” refers to a dielectric constant of a dielectric material of 2.0 or less, and preferably 1.5 or less. A wide variety of low-k materials may be employed in accordance with embodiments, for example, spin-on inorganic dielectrics, spin-on organic dielectrics, porous dielectric materials, organic polymer, organic silica glass, FSG (SiOF series material), HSQ (hydrogen silsesquioxane) series material, MSQ (methyl silsesquioxane) series material, or porous organic series material.

In some embodiments, the dielectric layer 1204 is deposited through any of a variety of techniques, such as chemical vapor deposition (CVD), physical vapor deposition (PVD), atomic layer deposition (ALD), remote plasma enhanced chemical vapor deposition (RPECVD), liquid source misted chemical deposition (LSMCD), coating, spin-coating or another process that is adapted to form a thin film layer over a semiconductor substrate.

In embodiments, the dielectric layer 1204 is a nitrogen-containing layer, a carbon-containing layer, or a carbon-containing and nitrogen-containing layer for increasing corrosion resistance during a subsequent chemical mechanical polishing (CMP) process and/or increasing electromigration resistance. In one embodiment, the dielectric layer 1204 is a silicon-containing and nitrogen-containing dielectric layer. In another embodiment, the dielectric layer 1204 is a silicon-containing and carbon-containing dielectric layer. In yet another embodiment, the dielectric layer 1204 is a silicon-containing, nitrogen-containing, and carbon-containing dielectric layer. In one embodiment, the dielectric layer 1204 has a ratio by weight of carbon to silicon about equal or greater than 0.5. In another embodiment, the dielectric layer 1204 has a ratio by weight of nitrogen to silicon about equal or greater than 0.3. In yet another embodiment, the dielectric layer 1204 has a ratio by weight of carbon to silicon about equal or greater than 0.5 and a ratio by weight of nitrogen to silicon about equal or greater than 0.3.

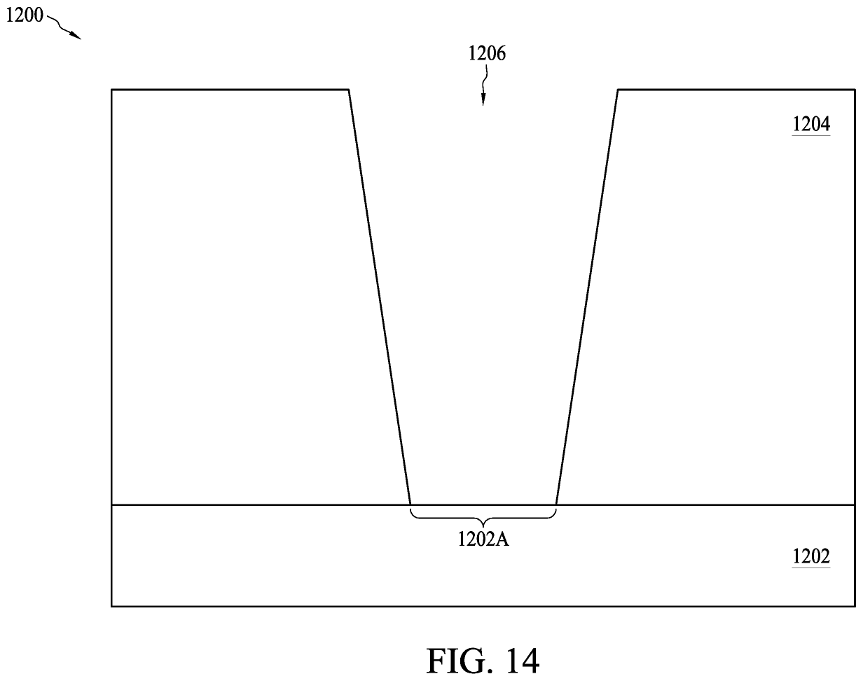

Referring to FIGS. 11 and 14, the method 1100 continues to step 1106 in which at least a portion (1202A) of the device feature 1202 is exposed, in accordance with various embodiments. In various embodiments, the portion 1202A is exposed, thereby allowing the disclosed stack of silicide layers to be formed at a position around the exposed portion 1202A. As shown, the portion 1202A is exposed by forming a recess (or cavity) 1206 extending through the dielectric layer 1204. The recess 1206 may be formed by performing at least some of the following processes: forming a patternable layer (e.g., a hardmask layer and/or a photoresist layer) over the dielectric layer 1204; forming a hole extending through the patternable layer that defines a position of the recess 1206; etching the dielectric layer 1204, with the patternable layer serving as a mask, until the device feature 1202 is exposed; and removing the patternable layer.

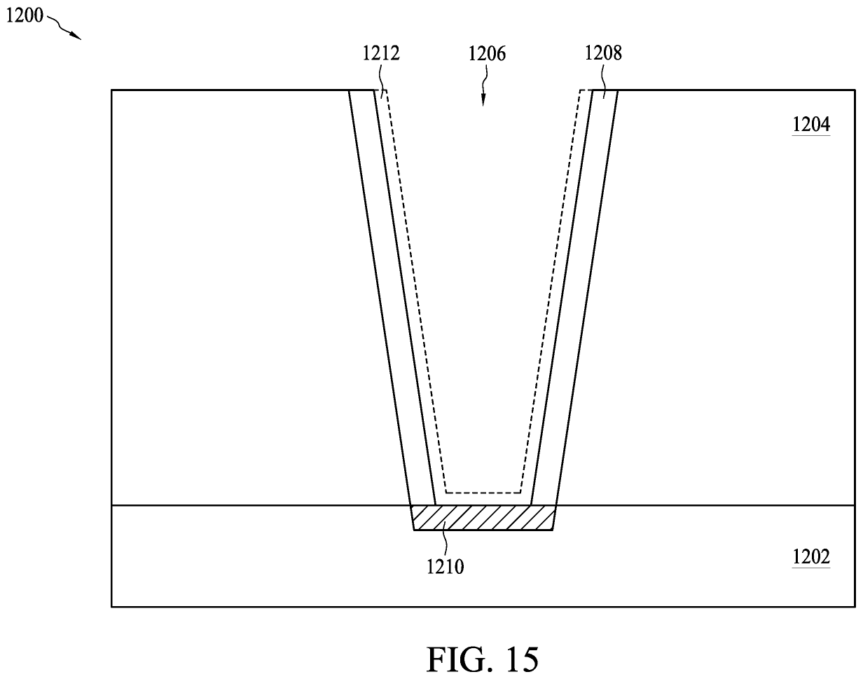

Referring to FIGS. 11 and 15, the method 1100 continues to step 1108 in which a titanium layer 1208 is formed and a first silicide layer 1210 is formed in the recess 1206, in accordance with various embodiments. In various embodiments, the titanium layer 1208 and first silicide layer 1210 may be (e.g., concurrently) formed in a same reaction chamber (sometimes referred to as in-situ formation).

Specifically, upon forming the recess 1206, the workpiece (i.e., the partially made semiconductor device 1200) may be transferred to a first chamber to remove any native oxide formed over surfaces of the dielectric layer 1204 and the device feature 1202 through plasma of argon. Such a first chamber may sometimes be referred to as a pre-clean chamber. Next, the workpiece may be transferred to a second chamber (e.g., a chemical vapor deposition (CVD) chamber). In the second chamber, the titanium layer 1208 may be first deposited as a (e.g., conformal) layer lining the recess 1206, e.g., extending along sidewalls of the recess 1206 and overlaying the exposed portion 1202A. The titanium layer 1208 may be deposited using a plasma-enhanced CVD tool, for example, through the following reaction: TiCl_{y}+H₂+Ar→TiClₓ+HCl+Ar. Such a second chamber may sometimes be referred to as a Ti chamber. Concurrently with forming the titanium layer 1208, a portion of the titanium layer 1208 that is at the bottom of the recess 1206 may react with the exposed portion 2102A having Si through a thermal process, thereby forming the first silicide layer 1210. The first silicide layer 1210 may be formed through the following reaction: TiClₓ+H₂+Si→TiSi₂+HCl. Accordingly, the first silicide layer 1210 can essentially consist of TiSi₂.

As shown, upon forming the first silicide layer 1210, the titanium layer 1208 extends along the sidewalls of the recess 1206, while the first silicide layer 1210 is disposed at the position of the exposed portion 1202A of the device feature 1202. In the illustrated embodiment of FIG. 15, the first silicide layer 1210 may be formed as having an upper surface that is substantially coplanar with at least a portion of an upper surface of the device feature 1202, e.g., the upper surface of the first silicide layer 1210 and at least the portion of the upper surface of the device feature 1202 sharing a common surface. Such a common surface may be substantially flat or curved. Alternatively stated, the first silicide layer 1210 may be recessed into the device feature 1202 with a depth of about 10 angstroms to about 500 angstroms. In some embodiments, the depth may be in the range of about 100 angstroms to about 200 angstroms. However, it should be understood that, in addition to the portion recessed into the device feature 1202, the first silicide layer 1210 may include some portions that also extend along the sidewalls of the recess 1206, in some other embodiments.

After forming the first silicide layer 1210, the workpiece may remain in the second chamber to form an optional titanium nitride layer 1212 extending the sidewalls of the recess 1206, as shown in FIG. 15. The titanium nitride layer 1212 may be formed by flowing nitrogen-based gas to the second chamber. For example, the titanium nitride layer 1212 may be formed through the following reaction: Ti+NH₃→TiN+H₂. In some embodiments, a thickness of the titanium layer 1208 and the titanium nitride layer 1212 (if formed) may be in the range of about 10 angstroms to about 200 angstroms.

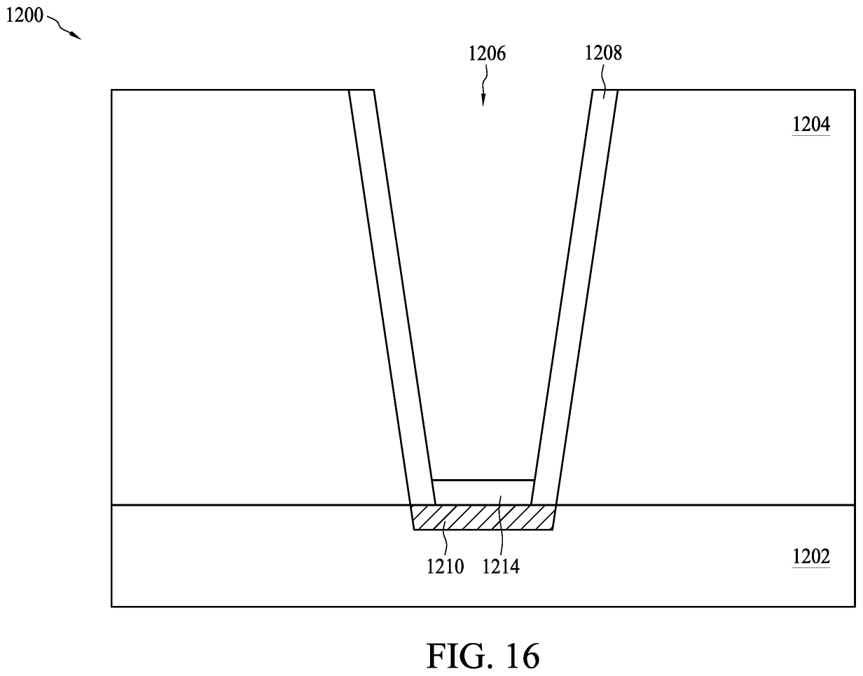

Referring to FIGS. 11 and 16, the method 1100 continues to step 1110 in which a patterned silicon layer 1214 is formed in the recess 1206, in accordance with various embodiments. As shown, the patterned silicon layer 1214 may be formed as a (e.g., conformal) layer at a bottom of the recess 1206 (i.e., extending along a relatively small bottom portions of the sidewalls of the recess 1206).

In various embodiments, the patterned silicon layer 1214, in the form of poly-Si or amorphous Si, is formed through a CVD process or a diffusion process, followed by an etching process. The formation of the patterned silicon layer 1214 may be performed in a third chamber different from the pre-clean (first) chamber and from the titanium (second) chamber. For example, a blanket silicon layer can be formed using a CVD process at an elevated temperature of about 200° C. to about 300° C. based on the following reaction: SiHₓ→Si+xH. In another example, a blanket silicon layer can be formed using a diffusion process at an elevated temperature of about 500° C. to about 650° C. based on the following reaction: SiH₄→Si+2H₂. Through any of the above processes, the blanket silicon layer may be formed as a layer lining the recess 1206, i.e., overlaying the bottom of the recess 1206 and extending along sidewalls of the recess 1206. Next, some portions of the blanket silicon layer that extend along the sidewalls of the recess 1206 may be removed (or otherwise patterned) by the following etching process, resulting in the patterned silicon layer 1214 as shown in FIG. 16.

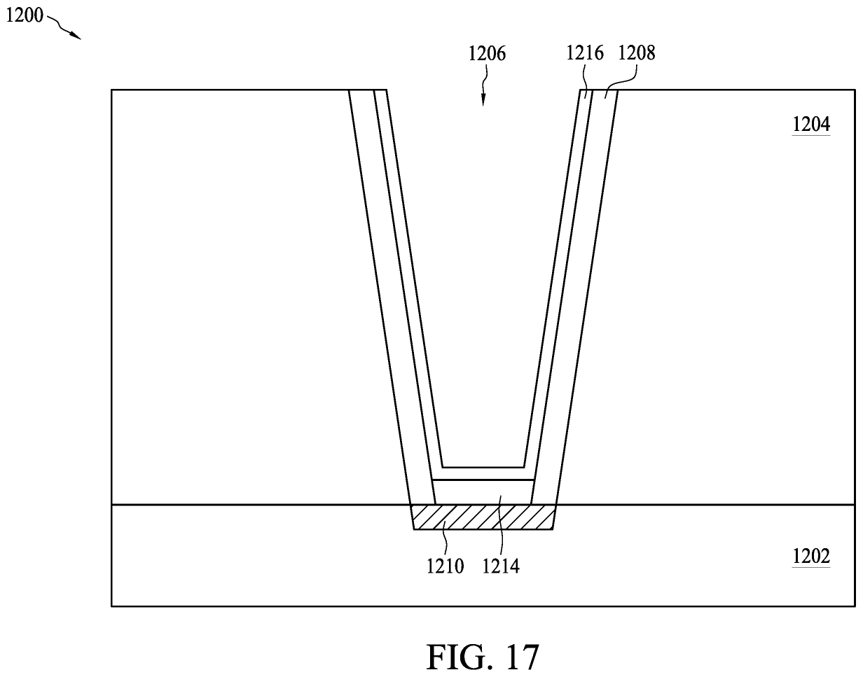

Referring to FIGS. 11 and 17, the method 1100 continues to step 1112 in which a nickel layer 1216 is formed in the recess 1206, in accordance with various embodiments. As shown, the nickel layer 1216 may be formed as a (e.g., conformal) layer lining the recess 1206.

In various embodiments, the nickel layer 1216 may be formed in a fourth chamber different from the pre-clean (first) chamber, from the titanium (second) chamber, and from the silicon (third) chamber. Specifically, upon forming the patterned silicon layer 1214, the workpiece may be transferred to the first chamber to remove any native oxide through one or more chemical etching processes. Next, the workpiece may be transferred to a fourth chamber (e.g., a chemical vapor deposition (CVD) chamber or physical vapor deposition (PVD) chamber) to deposit the nickel layer 1216. Such a fourth chamber may sometimes be referred to as a Ni chamber.

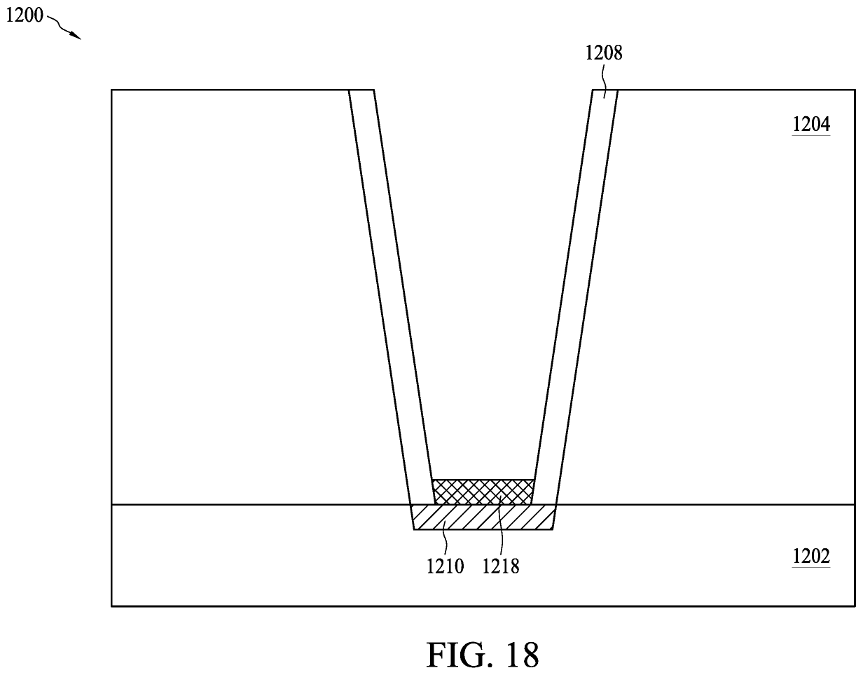

Referring to FIGS. 11 and 18, the method 1100 continues to step 1114 in which a second silicide layer 1218 is formed in the recess 1206, in accordance with various embodiments. As shown, the second silicide layer 1218 may be formed as a (e.g., conformal) layer at the bottom of the recess 1206.

In various embodiments, the second silicide layer 1218 may be formed in the same Ni (fourth) chamber through one or more annealing processes. Specifically, the second silicide layer 1218 may be formed by annealing the workpiece at one or more elevated temperatures. As such, the nickel layer 1216 can react with the patterned silicon layer 1214, thereby forming the second silicide layer 1218. For example, after depositing the nickel layer 1216 in the Ni chamber, the workpiece is first annealed at a relatively low temperature (e.g., about 250° C.) for a relatively long period of time (e.g., about 60 seconds) to cause the nickel layer 1216 to react with the patterned silicon layer 1214, thereby forming NiSi₂. Unreacted nickel may be removed from the Ni chamber. Next, still in the Ni chamber, the workpiece is annealed at a relatively high temperature (e.g., about 450° C.) for a relatively short period of time (about 25 seconds) to convert the NiSi₂ into NiSi. Accordingly, the second silicide layer 1218 essentially consists of NiSi. In some embodiments, a thickness of the second silicide layer 1218 may be in the range of about 10 angstroms to about 500 angstroms.

Upon forming the second silicide layer 1218, the disclosed stack of silicide layers 1210 and 1218, each of which contains different metals, can be formed. With such a stacked configuration, various advantages can be provided over the existing silicide layers. For example, with the first silicide layer 1210 that contains titanium formed in (or otherwise in contact with) the Si-based device feature 1202, leakage current can be substantially suppressed. Further, with the second silicide layer 1218 that contains nickel disposed over (or otherwise in contact with) the first silicide layer 1210, a total of contact resistance of such a stack of silicide layers 1210 and 2118 can be averaged down, as NiSi generally has a much lower resistivity than TiSi₂ (e.g., about 14˜20 μΩ·cm as opposed to about 60˜80 μΩ·cm). As such, a contact structure (e.g., a plug which will be discussed below), formed to electrically couple the device feature 1202 to one or more other device features, can conduct current with substantially low leakage while experiencing a significantly limited amount of contact resistance.

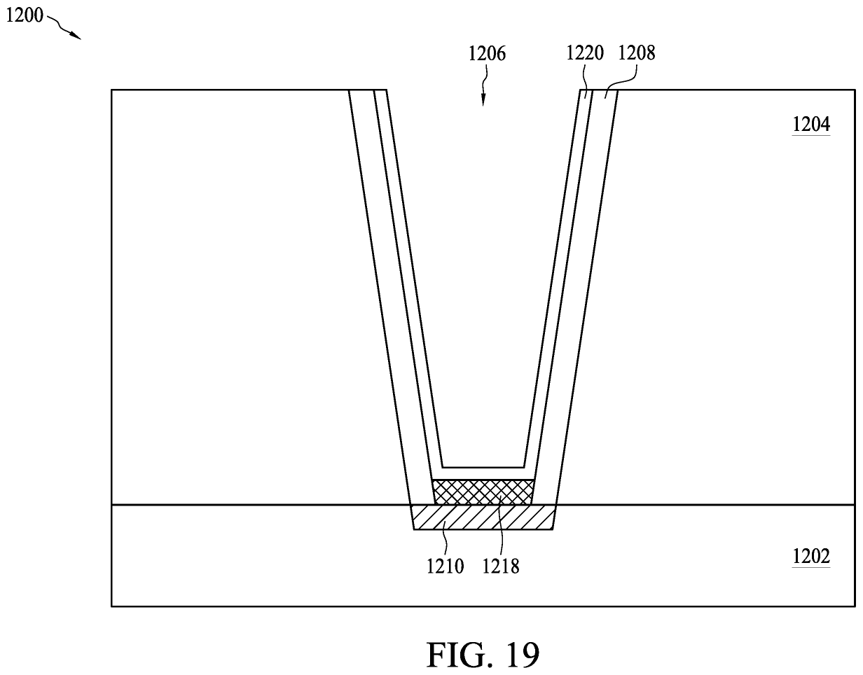

Referring to FIGS. 11 and 19, the method 1100 continues to step 1116 in which a barrier/glue layer 1220 is formed in the recess 1206, in accordance with various embodiments. As shown, the barrier/glue layer 1220 may be formed as a (e.g., conformal) layer lining the recess 1206.

In some embodiments, the barrier/glue layer 1220 can serve as a barrier to protect the overlaid components (e.g., the device feature 1202, the silicide layers 1210 and 1218, etc.) from being damaged during one or more later processes. Alternatively or additionally, the barrier/glue layer 1220 can serve as a glue layer to assure a later formed meal structure to be in close contact with the silicide layer 1218. The barrier/glue layer 1220 may be formed of titanium nitride, but it should be understood that the barrier/glue layer 1220 can be formed of any of various other materials (e.g., tantalum nitride, tantalum nitride silicon, titanium tungsten, titanium nitride silicon, or combinations thereof), while remaining within the scope of the present disclosure. The barrier/glue layer 1220 can be formed through a CVD process. The formation of the barrier/glue layer 1220 may be performed in a fifth chamber different from the above-described chambers. For example, after forming the second silicide layer 1218, the workpiece may be transferred from the fourth (Ni) chamber to a fifth chamber in which the barrier/glue layer 1220 is formed using a CVD process at an elevated temperature of about 540° C. based on the following reaction: TiCl_{y}+NH₃→TiN+HCl+N₂. Such a fifth chamber may sometimes be referred to as a TiN chamber.

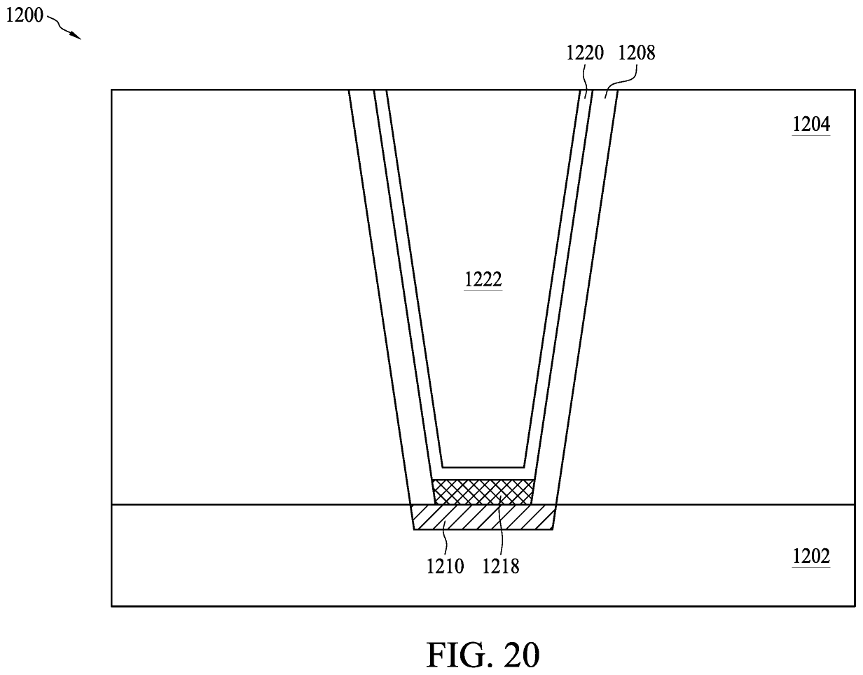

Referring to FIGS. 11 and 20, the method 1100 continues to step 1218 in which a plug 1222 is formed in the recess 1206 (FIG. 19), in accordance with various embodiments. As shown, the plug 1222 may be formed to fill (a remaining portion of) the recess 1206.

The plug 1222 is formed to allow the device feature 1202 to be electrically coupled to one or more other device features (e.g., one or more other source/drain terminals, one or more other gate terminals, one or more signal lines, one or more power rails, etc.). For example, the device feature 1202 can conduct electricity for the transistor to which the device feature 1202 belongs by applying a (e.g., voltage) signal on the plug 1222. Such a signal can be applied to the deice feature 1202 through the barrier/glue layer 1220, and the stack of silicide layers 1218 and 1210. With the second silicide layer 1218 interposed between the plug 1222 and the device feature 1202, the contact resistance between the plug and device feature 1202 can be significantly reduced.

In various embodiments, the plug 1222 is formed of a metal material such as, for example, tungsten. However, it should be understood that the plug 1222 can be formed of any of various other metal materials (e.g., copper, tantalum, indium, tin, zinc, manganese, chromium, titanium, platinum, aluminum, or combinations thereof), while remaining within the scope of the present disclosure. In some embodiments, the plug 1222 is formed using an electro-chemical plating (ECP) process, physical vapor deposition (PVD), chemical vapor deposition (CVD), plasma enhanced CVD (PECVD), low pressure CVD (LPCVD), atomic layer deposition (ALD), or other deposition techniques to deposit the above-mentioned metal material(s) into the recess 1206, followed by a chemical mechanical polishing (CMP) process.

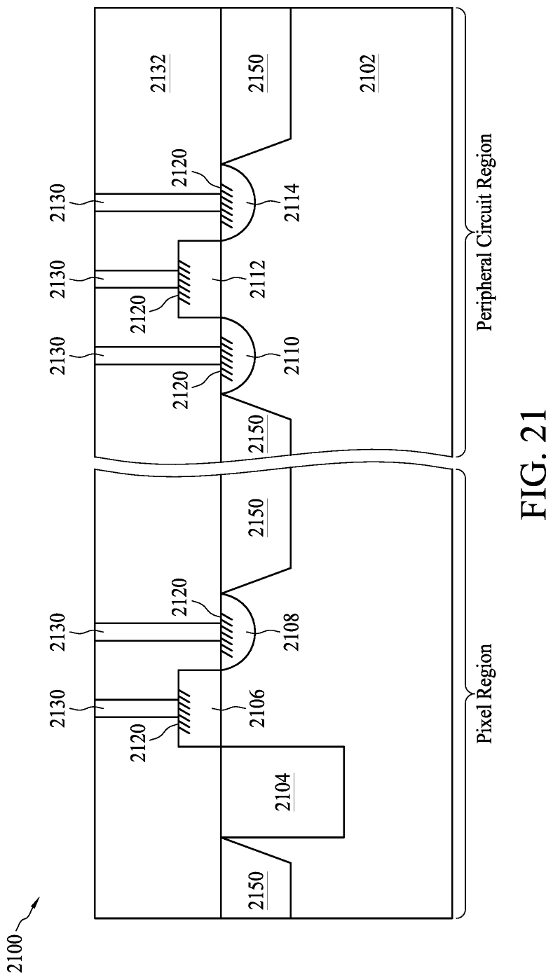

FIG. 21 illustrates a cross-sectional view of an example image sensor 2100 including a number of device features (e.g., 202, 1202) coupled to metal plugs (e.g., 222, 1222) through a number of the disclosed stacks of silicide layers (e.g., the stack of 210 and 218, the stack of 1210 and 1218), respectively. It should be understood that the image sensor 2100 is simplified for illustration purposes, and thus, the image sensor 2100 can include any of various other components, while remaining within the scope of the present disclosure.

As shown, the image sensor 2100 is formed on a semiconductor substrate 2102 having a pixel region and a peripheral circuit region. In general, the pixel region may include a number of active image sensing elements, such as photodiodes and transistors (e.g., transfer gate transistors, reset transistors), and the peripheral circuit region may include a number of transistors and other devices used for control and signal circuits.

Over the semiconductor substrate 2102, a number of isolation features (e.g., shallow trench isolation (STI) structures) 2150 are formed to define the different regions. Within each defined region, a number of devices/components can be formed and arranged. For example in the pixel region, the image sensor 2100 includes a photo-receiving element (e.g., a photodiode) 2104 generating electron-hole pairs (EHPs) from light incident thereon, a transfer gate terminal 2106, and a floating diffusion region 2108 arranged at a side of the photo-receiving element 2104. The image sensor 2100, in the peripheral circuit region, includes various semiconductor devices, for example, for removing noise from the output signal of the pixel region or for converting an analog signal into a digital signal. In the illustrated example of FIG. 21, however, the peripheral circuit region shows simply a single transistor for the convenience of description. For example, a transistor, constituted by a gate terminal 2112 and source/drain regions 2110 and 2114, is shown in the peripheral circuit region.

In accordance with various embodiments, each of the photo-receiving element 2104, transfer gate terminal 2106, floating diffusion region 2108, gate terminal 2112, and source/drain regions 2110 and 2114 may be an implementation of the above-discussed device feature. Over the substrate 2102, an insulation film 2132 is formed to electrically isolate such features. Although the insulation film 2132 is shown as a single layer, it should be understood that the insulation film 2132 can include a number of insulation or dielectric layers stacked on top of one another. For example, the insulation film 2132 can include one or more ILD/IMD layers discussed above. Further, the insulation film 2132 can include a resist protect oxide (RPO) film optionally covering the photo-receiving element 2104 in the peripheral region. Still further, the insulation film 2132 can include an etch stop layer lining each of the device features, with an opening configured for forming a contact (e.g., a metal plug).

As discussed above, the disclosed methods (e.g., FIGS. 1 and 10) can be used to form stacks of multiple different silicide layers at the contacts universally across the pixel region and peripheral circuit region of an image sensor, while being immune from the issues that the existing image sensors are facing. For example in FIG. 21, the transfer gate terminal 2106, floating diffusion region 2108, gate terminal 2112, and source/drain regions 2110 and 2114 are each (e.g., physically and electrically) coupled to a plug 2130 through a stack of silicide layers 2120. Although the stack 2120 is shown as being embedded in the respective device feature, it should be understood that the stack 2120 includes a first silicide layer embedded within a device feature and a second silicide layer disposed above such a device feature (similar to the stack of silicide layers 210 and 218, or the stack of silicide layers 1210 and 1218).

In one aspect of the present disclosure, a semiconductor device is disclosed. The semiconductor device includes a device feature. The semiconductor device includes a first silicide layer having a first metal, wherein the first silicide layer is embedded in the device feature. The semiconductor device includes a second silicide layer having a second metal, wherein the second silicide layer, disposed above the device feature, comprises a first portion directly contacting the first silicide layer. The first metal is different from the second metal.

In another aspect of the present disclosure, a semiconductor device is disclosed. The semiconductor device includes a transistor comprising at least one terminal that contains silicon. The semiconductor device includes a metal plug electrically coupled to the at least one terminal. The semiconductor device includes a first silicide layer disposed between the metal plug and the at least one terminal, and having a first metal. The semiconductor device includes a second silicide layer comprising a first portion disposed between the metal plug and the at least one terminal, and having a second metal. The first metal is different from the second metal.

In yet another aspect of the present disclosure, a method for fabricating semiconductor devices is disclosed. The method includes forming a recess extending through a dielectric layer to expose a portion of a silicon-based device feature. The method includes forming a first silicide layer at a position of the exposed portion of the silicon-based device feature, wherein the first silicide layer contains a first metal. The method includes forming a second silicide layer over the first silicide layer, wherein the second silicide layer contains a second metal different from the first metal. The method includes forming a metal plug within the recess.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a device feature;
a first silicide layer having a first metal, wherein the first silicide layer is embedded in the device feature; and
a second silicide layer having a second metal, wherein the second silicide layer, disposed above the device feature, comprises a first portion directly contacting the first silicide layer;
wherein the first metal is different from the second metal.

2. The semiconductor device of claim 1, wherein the first metal includes titanium and the second metal includes nickel.

3. The semiconductor device of claim 1, wherein the device feature has a first upper surface and the first silicide layer has a second upper surface, and wherein the first upper surface and the second upper surface share a common surface.

4. The semiconductor device of claim 1, further comprising:
a dielectric layer disposed over the device feature and having a recess extending through the dielectric layer;
a metal layer comprising at least the first metal and extending along inner sidewalls of the recess;
a metal plug disposed within the recess, wherein the metal plug is configured to electrically couple the device feature to an interconnect structure via a combination of the first silicide layer and second silicide layer.

5. The semiconductor device of claim 4, wherein the metal layer is in contact with end portions of an upper surface of the first silicide layer.

6. The semiconductor device of claim 4, wherein the second silicide layer further comprises a second portion extending along the inner sidewalls of the recess.

7. The semiconductor device of claim 4, further comprising a nitride layer having the first metal and disposed between metal plug and the recess.

8. The semiconductor device of claim 7, wherein the nitride layer is in contact with at least a portion of an upper surface of the second silicide layer.

9. The semiconductor device of claim 1, wherein the device feature includes a silicon-based structure or region that serves as a drain/source terminal of a transistor.

10. The semiconductor device of claim 1, wherein the device feature includes a poly-silicon structure that serves as a gate terminal of a transistor.

11. The semiconductor device of claim 1, wherein the first silicide layer has a first resistivity and the second silicide layer has a second resistivity, and wherein the second resistivity is less than the first resistivity.

12. A semiconductor device, comprising:
a transistor comprising at least one terminal that contains silicon;
a metal plug electrically coupled to the at least one terminal;
a first silicide layer disposed between the metal plug and the at least one terminal, and having a first metal; and
a second silicide layer comprising a first portion disposed between the metal plug and the at least one terminal, and having a second metal;
wherein the first metal is different from the second metal.

13. The semiconductor device of claim 12, wherein the first silicide layer includes titanium silicide (TiSi₂), and the second silicide layer includes nickel silicide (NiSi).

14. The semiconductor device of claim 12, wherein the first silicide layer is embedded within the terminal, with an upper surface exposed from an upper surface of the terminal.

15. The semiconductor device of claim 12, wherein the second silicide layer, in direct contact with the first silicide layer, further comprises a second portion extending along sidewalls of the metal plug.

16. The semiconductor device of claim 12, wherein the second silicide layer, in direct contact with the first silicide layer, has sidewalls inwardly recessed from sidewalls of the first silicide layer, respectively.

17. A method for fabricating semiconductor devices, comprising:
forming a recess extending through a dielectric layer to expose a portion of a silicon-based device feature;
forming a first silicide layer at a position of the exposed portion of the silicon-based device feature, wherein the first silicide layer contains a first metal;
forming a second silicide layer over the first silicide layer, wherein the second silicide layer contains a second metal different from the first metal; and
forming a metal plug within the recess.

18. The method of claim 17, wherein the first silicide layer includes titanium silicide (TiSi₂), and the second silicide layer includes nickel silicide (NiSi).

19. The method of claim 17, wherein the step of forming a second silicide layer over the first silicide layer further comprises:
depositing a silicon layer lining the recess;
depositing a metal layer, containing the second metal, that lines the recess; and
annealing the silicon layer and metal layer to form the second silicide layer.

20. The method of claim 17, wherein the step of forming a second silicide layer over the first silicide layer further comprises:
depositing a silicon layer lining the recess;
etching portions of the silicon layer that extend along inner sidewalls of the recess, respectively;
depositing a metal layer, containing the second metal, that lines the recess; and
annealing the silicon layer and metal layer to form the second silicide layer.
